(19) United States
(12) Patent Application Publication
(10) Pub. No.: US 2024/0175629 A1
(43) Pub. Date: May 30, 2024

(54) SUBSTRATE PROCESSING BAFFLE, SUBSTRATE PROCESSING APPARATUS INCLUDING THE SAME, AND PROCESSING APPARATUS FABRICATION METHOD

(71) Applicant: Samsung Electronics Co., Ltd., Suwon-si (KR)

(72) Inventors: SANGJINE PARK, Suwon-si (KR); Ji Hwan PARK, Suwon-si (KR); KUNTACK LEE, Suwon-si (KR)

(21) Appl. No.: 18/334,011

(22) Filed: Jun. 13, 2023

(30) Foreign Application Priority Data
Nov. 29, 2022 (KR) 10-2022-0163346

(51) Int. Cl. F26B 5/00; F26B 25/16

(52) U.S. Cl. CPC F26B 5/005; F26B 25/16

(57) ABSTRACT

Disclosed are substrate processing baffles, substrate processing apparatuses, and substrate processing apparatus fabrication methods. The substrate processing baffle comprises a plate body having a central axis that extends in a first direction, and an upper body on the plate body. The upper body includes an upper flow path connected to a top surface of the upper body. The plate body includes a lower flow path connected to the upper flow path and a bottom surface of the plate body, and a coupling hole extending through a top surface of the plate body. The coupling hole includes a placement hole. The placement hole includes a position setting aperture whose width decreases with decreasing distance from the top surface of the plate body.

### CROSS-REFERENCE TO RELATED APPLICATION

This U.S. nonprovisional application claims priority under 35 U.S.C § 119 to Korean Patent Application No. 10-2022-0163346 filed on Nov. 29, 2022 in the Korean Intellectual Property Office, the disclosure of which is hereby incorporated by reference in its entirety.

### BACKGROUND

Aspects of the present inventive concept relate to a substrate processing baffle, a substrate processing apparatus including the same, and a substrate processing apparatus fabrication method, and more particularly, to a substrate processing baffle capable of placing a baffle on an exact position, a substrate processing apparatus including the same, and a substrate processing apparatus fabrication method.

A semiconductor device may be fabricated through various processes. For example, the semiconductor device may be manufactured through a photolithography process, an etching process, a deposition process, and a plating process. During a photolithography process for fabricating a semiconductor device, a wet process may be performed to coat liquid, such as a developer, on a wafer. In addition, a dry process may be executed to remove the liquid coated on the wafer. Various methods may be used to coat the liquid on the wafer or to remove the liquid from the wafer.

### SUMMARY

Some embodiments of the present inventive concept provide a substrate processing baffle capable of being exactly combined with an upper chamber, a substrate processing apparatus including the same, and a substrate processing apparatus fabrication method.

Some embodiments of the present inventive concept provide a substrate processing baffle capable of uniformly providing a fluid onto a substrate, a substrate processing apparatus including the same, and a substrate processing apparatus fabrication method.

Some embodiments of the present inventive concept provide a substrate processing baffle capable of being promptly and easily coupled to an upper chamber, a substrate processing apparatus including the same, and a substrate processing apparatus fabrication method.

Some embodiments of the present inventive concept provide a substrate processing baffle capable of increasing a substrate manufacturing yield, a substrate processing apparatus including the same, and a substrate processing apparatus fabrication method.

Aspects of the present inventive concept are not limited to the mentioned above, and other aspects which have not been mentioned above will be clearly understood to those skilled in the art from the following description.

According to some embodiments of the present inventive concept, a substrate processing baffle may comprise a plate body having a central axis that extends in a first direction and an upper body on the plate body. The upper body may provide an upper flow path connected to a top surface of the upper body. The plate body may include a lower flow path connected to the upper flow path and a bottom surface of the plate body; and a coupling hole connected to a top surface of the plate body. The coupling hole may include a placement hole. The placement hole may include a position setting aperture whose width decreases with decreasing distance from the top surface of the plate body.

According to some embodiments of the present inventive concept, a substrate processing apparatus may comprise a dry chamber housing that provides a drying space a substrate processing baffle in the dry chamber housing; and a coupling member that connects the dry chamber housing and the substrate processing baffle to each other. The substrate processing baffle may include a plate body. The plate body may include a lower flow path connected to a bottom surface of the plate body; and a coupling hole extending through a top surface of the plate body. The coupling hole may include a placement hole. At least a portion of the placement hole may be defined by an inclined inner surface inclined toward an axis of the placement hole. The axis may extend vertically. A portion of a lateral surface of the coupling member may be in contact with the inclined inner surface.

According to some embodiments of the present inventive concept, a substrate processing apparatus fabrication method may comprise placing a substrate processing baffle below an upper chamber of a dry chamber housing; inserting a coupling member into the substrate processing baffle; and descending the substrate processing baffle to fix the coupling member to the substrate processing baffle. The substrate processing baffle may include a plate body having a central axis that extends in a first direction. The plate body may include: a lower flow path connected to a bottom surface of the plate body; and a coupling hole extending through a top surface of the plate body. The coupling hole may include a placement hole. The placement hole may include a position setting aperture whose width decreases with decreasing distance from the top surface of the plate body. The step of inserting the coupling member into the substrate processing baffle may include inserting the coupling member into the coupling hole. The step of descending the substrate processing baffle may include fixing the coupling member into the placement hole.

Details of other example embodiments are included in the description and drawings.

### BRIEF DESCRIPTION OF THE DRAWINGS

FIG. 1 illustrates a simplified schematic diagram showing a substrate processing system according to some embodiments of the present inventive concept.

FIG. 2 illustrates a cross-sectional view showing a cleaning chamber according to some embodiments of the present inventive concept.

FIG. 3 illustrates a cross-sectional view showing a dry chamber according to some embodiments of the present inventive concept.

FIG. 4 illustrates an enlarged cross-sectional view partially showing a dry chamber according to some embodiments of the present inventive concept.

FIG. 5 illustrates an enlarged cross-sectional view showing section X of FIG. 4.

FIG. 6 illustrates a cross-sectional view showing a coupling member according to some embodiments of the present inventive concept.

FIG. 7 illustrates a perspective view showing a substrate processing baffle and a coupling member according to some embodiments of the present inventive concept.

FIG. 8 illustrates a cut-away perspective view showing a substrate processing baffle and a coupling member according to some embodiments of the present inventive concept.

FIG. 9 illustrates a plan view showing a substrate processing baffle according to some embodiments of the present inventive concept.

FIG. 10 illustrates a cross-sectional view showing a substrate processing baffle according to some embodiments of the present inventive concept.

FIG. 11 illustrates a simplified schematic diagram showing a supercritical fluid supply according to some embodiments of the present inventive concept.

FIG. 12 illustrates a flow chart showing a substrate processing apparatus fabrication method according to some embodiments of the present inventive concept.

FIGS. 13 to 21 illustrate diagrams showing the substrate processing apparatus fabrication method of FIG. 12.

FIG. 22 illustrates a flow chart showing a substrate processing method according to some embodiments of the present inventive concept.

FIGS. 23 and 24 illustrate diagrams showing a substrate processing method according to the flow chart of FIG. 22.

### DETAIL PARTED DESCRIPTION OF EMBODIMENTS

The following will now describe some embodiments of the present inventive concept with reference to the accompanying drawings. Like reference numerals may indicate like components throughout the description.

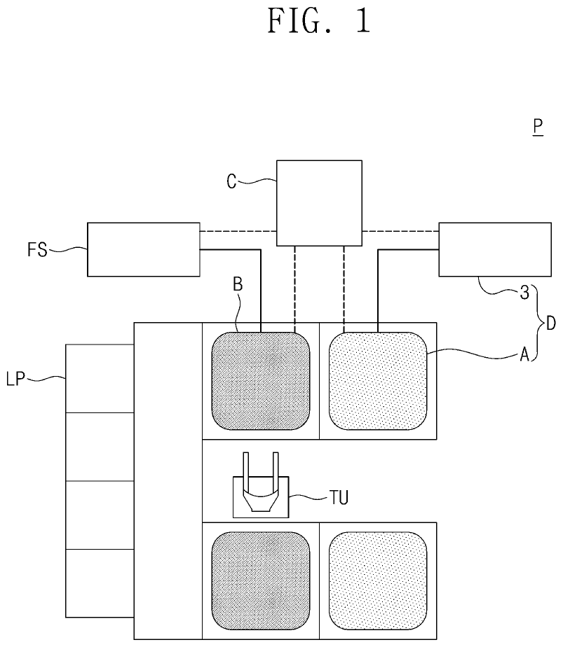

FIG. 1 illustrates a simplified schematic diagram showing a substrate processing system according to some embodiments of the present inventive concept.

Referring to FIG. 1, a substrate processing system P may be provided. The substrate processing system P may be a device to process a substrate in semiconductor fabrication process. For example, the substrate processing system P may be configured to execute a wet process and a dry process on a substrate. For example, the substrate processing system P may provide a substrate with fluid to wet the substrate or may remove fluid from a substrate to dry and clean the substrate. The substrate processing system P may spray a developer on a substrate that has experienced an extreme ultraviolet (EUV) exposure process. In addition, the substrate processing system P may dry a developer on a substrate. In this description, the term “substrate” may indicate a semiconductor wafer. The wafer may include a silicon (Si) wafer, but aspects of the present inventive concept are not limited thereto. The substrate processing system P may include a loading port LP, a wet chamber B, a wetting solution supply FS, a transfer unit TU, a substrate processing apparatus D, and a controller C.

The loading port LP may be a port on which a substrate is loaded. For example, the loading port LP may load thereon a substrate that has experienced various semiconductor fabrication processes. The loading port LP may be provided in plural. A plurality of substrates may be correspondingly loaded on each of the plurality of loading ports LP. Unless otherwise especially noted, one loading port LP will be discussed.

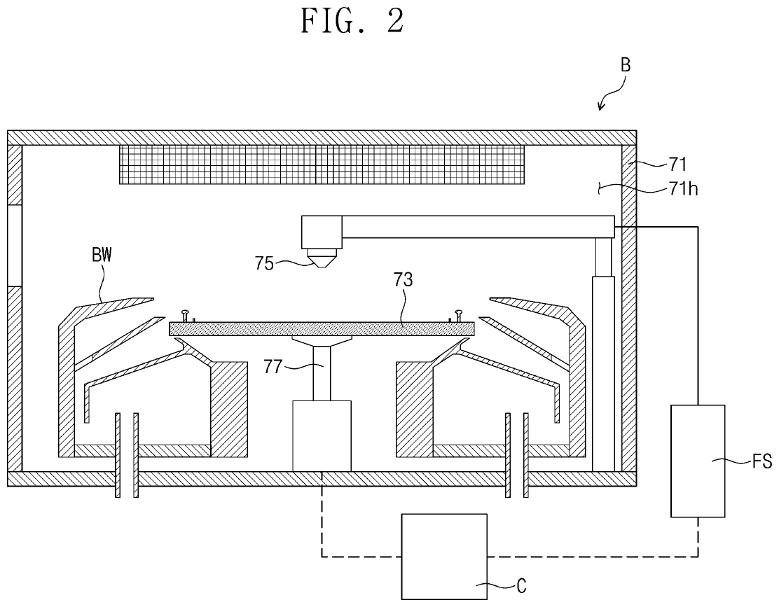

The wet chamber B may be a chamber in which a wet process is performed on a substrate. The wet chamber B may provide a space where a wet process is performed. When a substrate is disposed in the wet chamber B, the substrate may be coated thereon with liquid, such as various chemicals and/or isopropyl alcohol (IPA). The liquid coating may be fulfilled in various ways. For example, a liquid may be sprayed on a substrate that rotates, and a centrifugal force may cause the liquid to uniformly distribute on the substrate. The wet chamber B may be provided in plural. For example, two wet chambers B may be provided. The two wet chambers B may be disposed to face each other. A single wet chamber B, however, will be discussed below. The wet chamber B will be further discussed in detail below with reference to FIG. 2.

The wetting solution supply FS may supply the wet chamber B with fluid. The wetting solution supply FS may include a fluid tank, a pump, and so forth. A wetting solution may be defined to indicate a fluid with which the wetting solution supply FS supplies the wet chamber B. The wetting solution may include various chemicals and/or water. For example, the wetting solution may include a developer or isopropyl alcohol (IPA).

The transfer unit TU may transfer a substrate. For example, the transfer unit TU may transfer a substrate loaded on the loading port LP to the wet chamber B. In addition, the transfer unit TU may unload a substrate from the wet chamber B, and may then transfer the unloaded substrate to a dry chamber A which will be discussed below. The transfer unit TU may include an actuator such as a motor. A single transfer unit TU may be provided, but aspects of the present inventive concept are not limited thereto.

The substrate processing apparatus D may dry a substrate. The substrate processing apparatus D may include a dry chamber A and a supercritical fluid supply 3.

The dry chamber A may be a chamber to dry a substrate. For example, the dry chamber A may dry and/or clean a substrate that has passed through the wet chamber B. For example, the dry chamber A may remove liquid from a substrate on which the liquid, such as a developer and/or isopropyl alcohol (IPA), is coated in the wet chamber B. The dry chamber A may provide a space where a dry process is performed. The dry chamber A may be provided in plural. For example, two dry chambers A may be provided. The two dry chambers A may be disposed to face each other. A single dry chamber A, however, will be discussed below.

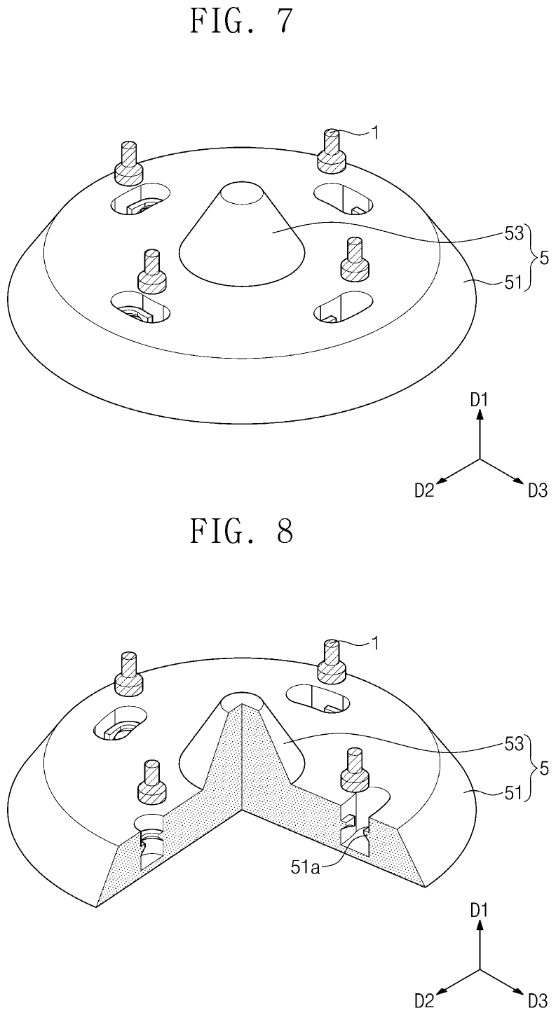

The supercritical fluid supply 3 may supply the dry chamber A with fluid. The supercritical fluid supply 3 may supply a supercritical fluid that is sprayed into the dry chamber A. For example, the supercritical fluid supply 3 may supply the dry chamber A with carbon dioxide (CO₂) in its supercritical fluid (SCF) state. The supercritical fluid supply 3 will be further discussed in detail below with reference to FIG. 7.

The controller C may control the wet chamber B and the dry chamber A. For example, the controller C may control the supercritical fluid supply 3 to adjust the degree of dryness of a substrate. For example, the controller C may change an amount of fluid that is supplied to the dry chamber A.

FIG. 2 illustrates a cross-sectional view showing a cleaning chamber according to some embodiments of the present inventive concept.

Referring to FIG. 2, the wet chamber B may include a wet chamber housing 71, a wetting stage 73, a wetting nozzle 75, a rotating shaft 77, and a bowl BW.

The wet chamber housing 71 may provide a wetting space 71h. A wet process may be performed on a substrate disposed in the wetting space 71h.

The wetting stage 73 may be positioned in the wet chamber housing 71. The wetting stage 73 may support a substrate. For example, a substrate inserted into the wet chamber housing 71 may be disposed on the wetting stage 73. The wetting stage 73 may rotate a substrate. The wetting stage 73 may extend in a second direction D2 and a third direction D3 perpendicular to the second direction D2.

The wetting nozzle 75 may be upwardly (e.g., in a first (vertical) direction D3 perpendicular to the second and third directions) spaced apart from the wetting stage 73. The wetting nozzle 75 may be connected to the wetting solution supply FS. The wetting nozzle 75 may be supplied with the wetting solution from the wetting solution supply FS, and may spray the wetting solution toward the wetting stage 73.

The controller C may control the rotating shaft 77 to rotate the wetting stage 73. Accordingly, a substrate disposed on the wetting stage 73 may rotate along with the rotation of the wetting stage 73.

The bowl BW may surround the wetting stage 73. The bowl BW may collect the wetting solution that is outwardly pushed from the wetting stage 73.

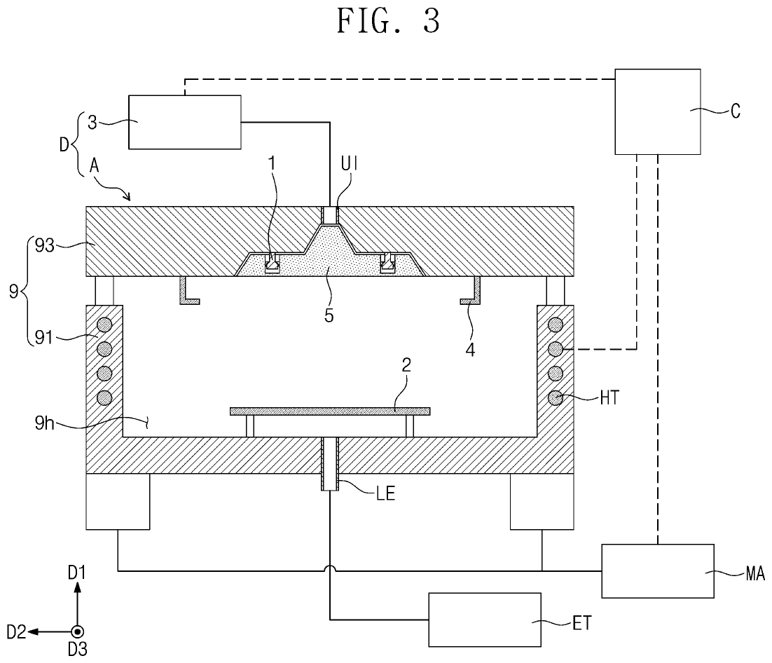

FIG. 3 illustrates a cross-sectional view showing a dry chamber according to some embodiments of the present inventive concept.

The first direction D1 may be called a vertical direction. In addition, each of the second and third directions D2 and D3 may be called a horizontal direction.

Referring to FIG. 3, the dry chamber A may dry a substrate. For example, the dry chamber A may remove liquid from a substrate. The dry chamber A may dry a substrate that has been wetted in the wet chamber (see B of FIG. 2). The dry chamber A may include a dry chamber housing 9, a dry heater HT, a dry chuck 4, a blocking plate 2, a chamber driving mechanism MA, an exhaust tank ET, a substrate processing baffle 5, and a coupling member 1.

The dry chamber housing 9 may provide a drying space 9h. The dry chamber housing 9 may include a lower chamber 91 and an upper chamber 93. The lower chamber 91 may be downwardly spaced apart (e.g., in the first direction D1) from the upper chamber 93. The drying space 9h may be provided between the lower chamber 91 and the upper chamber 93. The lower chamber 91 may be vertically movable. For example, the chamber driving mechanism MA may drive the lower chamber 91 to move upwardly to combine with the upper chamber 93. The lower chamber 91 and the upper chamber 93 may be combined to separate the drying space 9h from an external environment. A fluid inlet UI may be provided to the upper chamber 93. The fluid inlet UI may be connected to the supercritical fluid supply 3. A supercritical fluid may be supplied from the supercritical fluid supply 3 through the fluid inlet UI to the drying space 9h. A lower outlet LE may be provided to the lower chamber 91. The lower outlet LE may be connected to the exhaust tank ET. A fluid may be outwardly discharged through the lower outlet LE from the dry chamber housing 9.

The dry heater HT may be coupled to the dry chamber housing 9. The dry heater HT may heat the drying space 9h. The heating of the dry heater HT may permit a supercritical fluid introduced into the drying space 9h to maintain its supercritical state.

The dry chuck 4 may be connected to the upper chamber 93. The dry chuck 4 may be engaged with the upper chamber 93. A substrate may be disposed on the dry chuck 4. For example, the dry chuck 4 may support a substrate. The dry chuck 4 will be further discussed in detail below.

The blocking plate 2 may be connected to the lower chamber 91. The blocking plate 2 may be upwardly spaced apart at a certain interval from the lower outlet LE. The blocking plate 2 may block a flow of fluid. The chamber driving mechanism MA may be associated with the lower chamber 91. The chamber driving mechanism MA may drive the lower chamber 91 to move vertically (i.e., in the first direction D1). The chamber driving mechanism MA may combine the lower chamber 91 with the upper chamber 93, or may separate the lower chamber 91 from the upper chamber 93. The chamber driving mechanism MA may include an actuator such as a motor. The exhaust tank ET may be connected to the lower outlet LE. The exhaust tank ET may receive a fluid that is discharged through the lower outlet LE.

The substrate processing baffle 5 may be positioned in the dry chamber housing 9. The substrate processing baffle 5 may be coupled to the upper chamber 93. The substrate processing baffle 5 may be positioned, for example, on the dry chuck 4. The dry chuck 4 may be disposed downwardly spaced apart from the substrate processing baffle 5. The substrate processing baffle 5 may be connected to the supercritical fluid supply 3. For example, the substrate processing baffle 5 may be connected through the fluid inlet UI to the supercritical fluid supply 3. A fluid supplied from the supercritical fluid supply 3 may be introduced to the drying space 9h after passing through the substrate processing baffle 5. The substrate processing baffle 5 will be further discussed in detail below.

The coupling member 1 may connect the substrate processing baffle 5 and the dry chamber housing 9 to each other. The coupling member 1 may be fixedly combined with the upper chamber 93. For example, a top end of the coupling member 1 may be welded to a bottom surface of the upper chamber 93, thereby being combined with the upper chamber 93. The coupling member 1 will be further discussed in detail below.

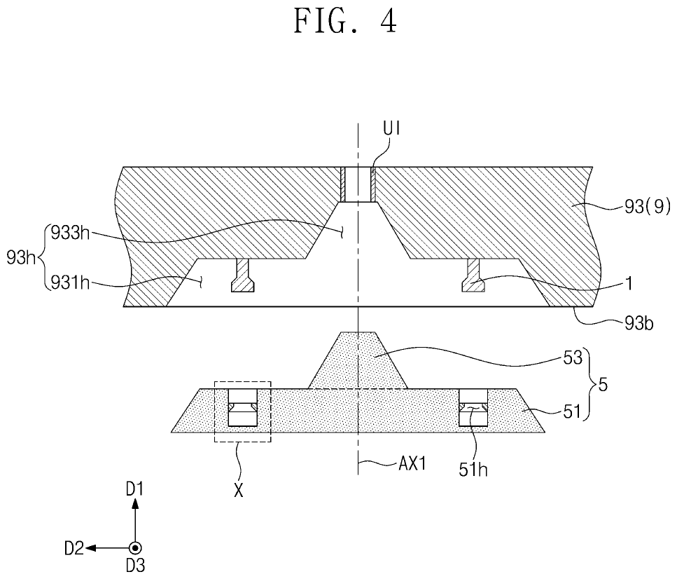

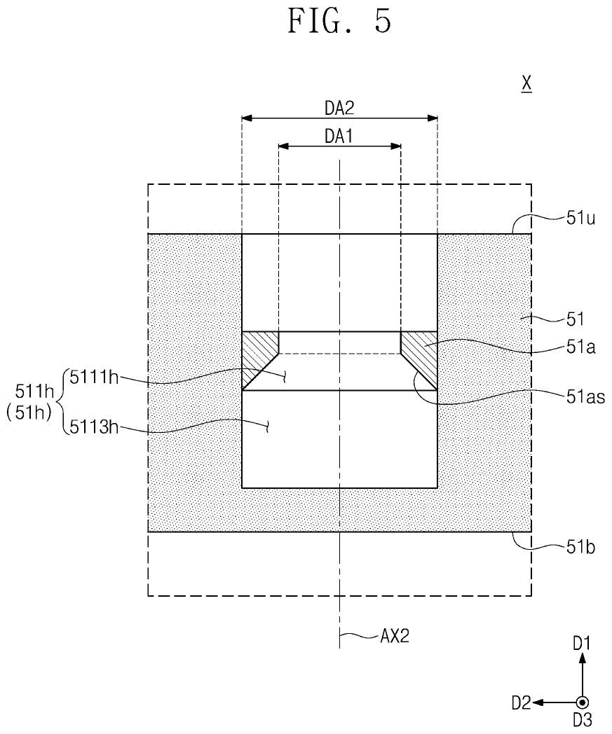

FIG. 4 illustrates an enlarged cross-sectional view partially showing a dry chamber according to some embodiments of the present inventive concept. FIG. 5 illustrates an enlarged cross-sectional view showing section X of FIG. 4.

Referring to FIGS. 4 and 5, the upper chamber 93 may provide a baffle placement space 93h. The substrate processing baffle 5 may be disposed in the baffle placement space 93h. The baffle placement space 93h may be a space that is upwardly recessed from a bottom surface 93b of the upper chamber 93. The baffle placement space 93h may be connected to the fluid inlet UI. For example, the fluid inlet UI may extend upwardly from the baffle placement space 93h. The baffle placement space 93h may include a lower space 931h and an upper space 933h. The lower space 931h may be connected to the bottom surface 93b of the upper chamber 93. The upper space 933h may connect the lower space 931h and the fluid inlet UI to each other. The upper space 933h may have a width less than that of the lower space 931h.

The coupling member 1 may be fixedly combined with the upper chamber 93. For example, in the baffle placement space 93h, the coupling member 1 may be rigidly placed on the bottom surface 93b of the upper chamber 93. For example, the coupling member 1 may be welded to the upper chamber 93.

The substrate processing baffle 5 may be coupled through the coupling member 1 to the upper chamber 93. The substrate processing baffle 5 may be disposed in the baffle placement space 93h. The substrate processing baffle 5 may include a plate body 51 and an upper body 53.

The plate body 51 may have a central axis AX1. The central axis AX1 may extend in the first direction D1. The plate body 51 may have a symmetric shape about the central axis AX1. The plate body 51 may have a diameter that decreases in an upward direction as shown in FIG. 4, but aspects of the present inventive concept are not limited thereto. The plate body 51 may include a coupling hole 51h. The plate body 51 may be positioned in the lower space 931h in a state where the substrate processing baffle 5 is combined with the upper chamber 93. The plate body 51 may include metal, but aspects of the present inventive concept are not limited thereto. The coupling hole 51h may extend through a top surface 51u of the plate body 51.

The upper body 53 may be positioned on the plate body 51. The upper body 53 may have an axis aligned with the central axis AX1 of the plate body 51. The upper body 53 may have a truncated cone shape, but aspects of the present inventive concept are not limited thereto. The upper body 53 may be positioned in the upper space 933h in a state where the substrate processing baffle 5 is combined with the upper chamber 93. The upper body 53 may include metal, but aspects of the present inventive concept are not limited thereto.

Referring to FIG. 5, the coupling hole 51h may be downwardly recessed from the top surface 51u of the plate body 51. The coupling hole 51h may have a height less than that of the plate body 51. Therefore, the coupling hole 51h may not be connected to (e.g., does not extend through) a bottom surface 51b of the plate body 51. The coupling hole 51h may include a placement hole 511h. The coupling member (see 1 of FIG. 4) may be disposed in the placement hole 511h. The placement hole 511h may have an axis AX2 that extends in the first direction D1. The placement hole 511h may include a position setting aperture 5111h and a lower aperture 5113h.

The position setting aperture 5111h may have a diameter that decreases in an upward direction. For example, a width of the position setting aperture 5111h may decrease with decreasing distance from the top surface 51u of the plate body 51. The position setting aperture 5111h may be defined by an inclined inner surface 51as. The inclined inner surface 51as may be inclined toward the axis AX2 of the placement hole 511h. For example, an upper portion of the inclined inner surface 51as may be inclined toward the axis AX2 of the placement hole 511h. In some embodiments, the inclined inner surface 51as may be an inner lateral surface of an inclination member 51a. The inclination member 51a may be a separate member that is coupled to the plate body 51. For example, the inclination member 51a and the plate body 51 may be integrally formed into a single unitary body. A first width DA1 may be defined to indicate a minimum width of the position setting aperture 5111h.

The lower aperture 5113h may be positioned below the position setting aperture 5111h. The lower aperture 5113h may be spatially connected to the position setting aperture 5111h. A width of the lower aperture 5113h may be constant, but aspects of the present inventive concept are not limited thereto. A second width DA2 may be defined to indicate the width of the lower aperture 5113h. The second width DA2 may be greater than the first width DA1.

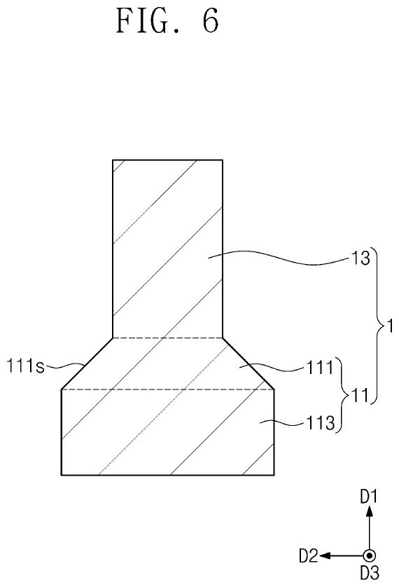

FIG. 6 illustrates a cross-sectional view showing a coupling member according to some embodiments of the present inventive concept.

Referring to FIG. 6, the coupling member 1 may include a coupling head 11 and a connection member 13.

The coupling head 11 may include an upper member 111 and a lower member 113. The upper member 111 may have a width that increases in a downward direction. The upper member 111 may have a lateral surface 111s that makes an acute angle with the first direction D1. For example, the lateral surface 111s of the upper member 111 may be inclined. The lateral surface 111s of the upper member 111 may be in contact with the inclined inner surface (see 51as of FIG. 5) in a state where the coupling member 1 and the substrate processing baffle (see 5 of FIG. 6) are combined with each other.

The upper member 111 may have, for example, a truncated cone shape. The lower member 113 may be positioned below the upper member 111. A width of the lower member 113 may be constant, but aspects of the present inventive concept are not limited thereto.

The connection member 13 may upwardly extend from the coupling head 11. A top end of the connection member 13 may be fixedly combined with the upper chamber (see 93 of FIG. 4).

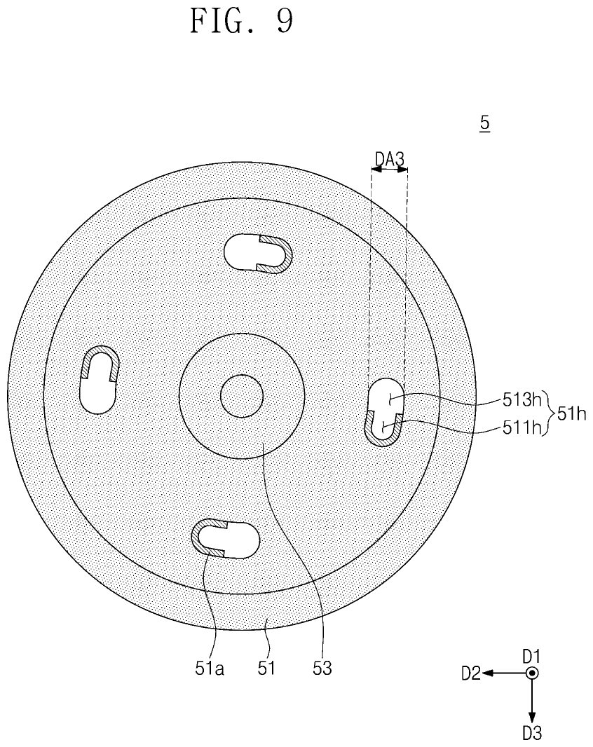

FIG. 7 illustrates a perspective view showing a substrate processing baffle and a coupling member according to some embodiments of the present inventive concept. FIG. 8 illustrates a cut-away perspective view showing a substrate processing baffle and a coupling member according to some embodiments of the present inventive concept. FIG. 9 illustrates a plan view showing a substrate processing baffle according to some embodiments of the present inventive concept.

Referring to FIGS. 7, 8, and 9, the coupling hole 51h may further include an insertion hole 513h. The insertion hole 513h may be positioned on a side of the placement hole 511h. For example, the insertion hole 513h and the placement hole 511h may be connected to each other in a horizontal direction. When viewed in plan, the insertion hole 513h and the placement hole 511h may extend in a circumferential direction. A third width DA3 may be defined to indicate a minimum width of the insertion hole 513h. The third width DA3 may be greater than the first width (see DA1 of FIG. 5).

The coupling hole 51h may be provided in plural. For example, four coupling holes 51h may be provided as shown in FIG. 7. The plurality of coupling holes 51h may be disposed spaced apart from each other in a circumferential direction. However, a single coupling hole 51h will be discussed below.

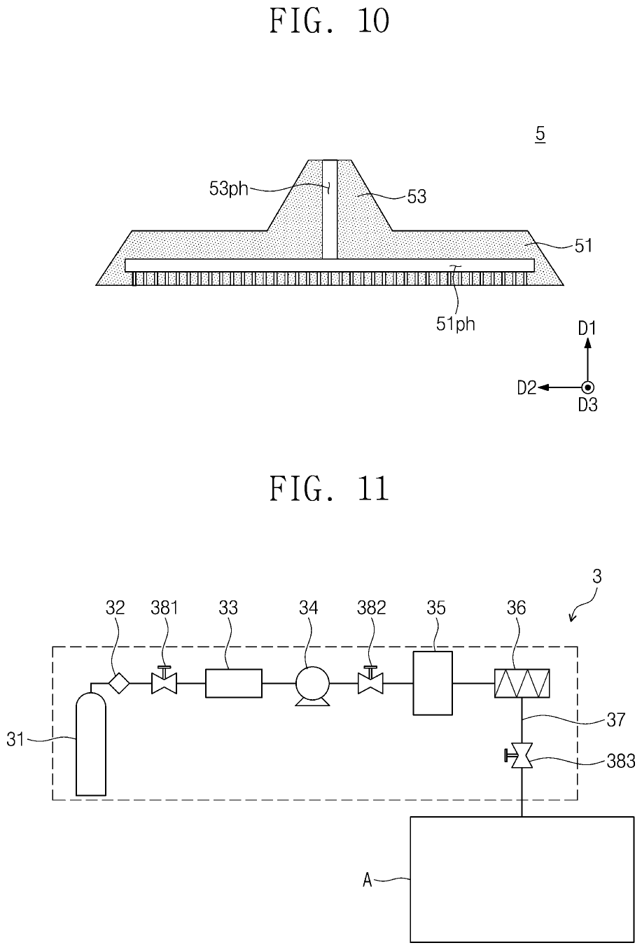

FIG. 10 illustrates a cross-sectional view showing a substrate processing baffle according to some embodiments of the present inventive concept.

Referring to FIG. 10, the upper body 53 may further provide an upper flow path 53ph. The upper flow path 53ph may be connected to a top surface of the upper body 53. The upper flow path 53ph may be connected to the fluid inlet (see UI of FIG. 4). Therefore, a fluid supplied from the supercritical fluid supply (see 3 of FIG. 3) may be introduced into the upper flow path 53ph. The upper flow path 53ph may be provided in plural. A plurality of flow paths may be dispersed in the upper body 53. In this sense, the upper body 53 may have a multi-channel structure. Unless otherwise especially stated, a single upper flow path 53ph will be discussed.

The plate body 51 may further provide a lower flow path 51ph. The lower flow path 51ph may be connected to (e.g., extends through) a bottom surface of the plate body 51. For example, the lower flow path 51ph may be exposed on the bottom surface of the plate body 51. The lower flow path 51ph may be spatially connected to the upper flow path 53ph. Therefore, a fluid supplied from the supercritical fluid supply (see 3 of FIG. 3) may move downwardly from the substrate processing baffle 5 after passing through the upper flow path 53ph and the lower flow path 51ph. The lower flow path 51ph may be provided in plural. A plurality of flow paths may be dispersed in the plate body 51. In this sense, the plate body 51 may have a multi-channel structure. Unless otherwise especially stated, a single lower flow path 51ph will be discussed.

The lower flow path 51ph may be spaced apart from the coupling hole (see 51h of FIG. 4). The lower flow path 51ph may not be connected to the coupling hole 51h. For example, FIG. 4 and FIG. 10 are cross-sections taken along different planes. Therefore, a fluid introduced into the lower flow path 51ph may not move into the coupling hole 51h. Aspects of the present inventive concept, however, are not limited thereto, and the lower flow path 51ph may not be spaced apart from the coupling hole 51h. For example, the lower flow path 51ph may be connected to the coupling hole 51h. In this case, a fluid introduced into the lower flow path 51ph may move into the coupling hole 51h.

FIG. 11 illustrates a simplified schematic diagram showing a supercritical fluid supply according to some embodiments of the present inventive concept.

Referring to FIG. 11, the supercritical fluid supply 3 may include a supercritical fluid source 31, a supercritical fluid line 37, a supply filter 32, a first valve 381, a condenser 33, a pump, a second valve 382, a tank 35, a heater 36, and a third valve 383.

The supercritical fluid source 31 may supply a supercritical fluid. For example, the supercritical fluid source 31 may store and supply a gaseous fluid which will be a supercritical fluid. When a supercritical fluid is a CO₂ supercritical fluid, the supercritical fluid source 31 may store CO₂ in a gaseous state. The gaseous CO₂ supplied from the supercritical fluid source 31 may have a temperature of about 10° C. to about 30° C. In addition, the gaseous CO₂ supplied from the supercritical fluid source 31 may have a pressure of about 4 MPa to about 6 MPa. A supercritical fluid supplied from the supercritical fluid source 31 may move along the supercritical fluid line 37.

The supercritical fluid line 37 may provide a pathway along which a supercritical fluid is introduced from the supercritical fluid source 31 to the dry chamber A. The supply filter 32 may be positioned on the supercritical fluid line 37. The supply filter 32 may filter foreign substances present in a supercritical fluid. The first valve 381 may control a fluid movement by opening or closing a flow path between the supply filter 32 and the condenser 33.

The condenser 33 may cool gaseous CO₂ supplied from the supercritical fluid source 31. Therefore, the gaseous CO₂ may be liquefied in the condenser 33. For example, the CO₂ liquefied in the condenser 33 may have a temperature of about 0° ° C. to about 6° C. In addition, the CO₂ liquefied in the condenser 33 may have a pressure of about 4 MPa to about 6 MPa.

The pump 34 may increase a pressure of supercritical fluid that is liquefied while passing through the condenser 33. For example, the pump 34 may provide a pressure between about 15 MPa and about 25 MPa to the CO₂ liquefied in the condenser 33. In addition, a temperature of CO₂ liquefied in the condenser 33 may become about 15° C. to about 25° C. while the CO₂ passes through the pump 34. The second valve 382 may control a fluid movement by opening or closing a flow path between the pump 34 and the tank 35. The tank 35 may store a supercritical fluid that is compressed by the pump 34.

The heater 36 may heat a supercritical fluid that moves along the supercritical fluid line 37. For example, the heater 36 may heat liquid CO₂ that is compressed by the pump 34. Therefore, the liquid CO₂ may become a supercritical state. The CO₂ that becomes a supercritical state by being heated by the heater 36 may be in a state of high temperature and high pressure. For example, the CO₂ that becomes a supercritical state while passing through the heater 36 may have a temperature of about 60° ° C. to about 90° C. In addition, the CO₂ that becomes a supercritical state while passing through the heater 36 may have a pressure of about 15 MPa to about 25 MPa. The third valve 383 may control a movement of the CO₂ that becomes a supercritical state while passing through the heater 36. The CO₂ in a supercritical state may be introduced into the dry chamber A after passing through the third valve 383.

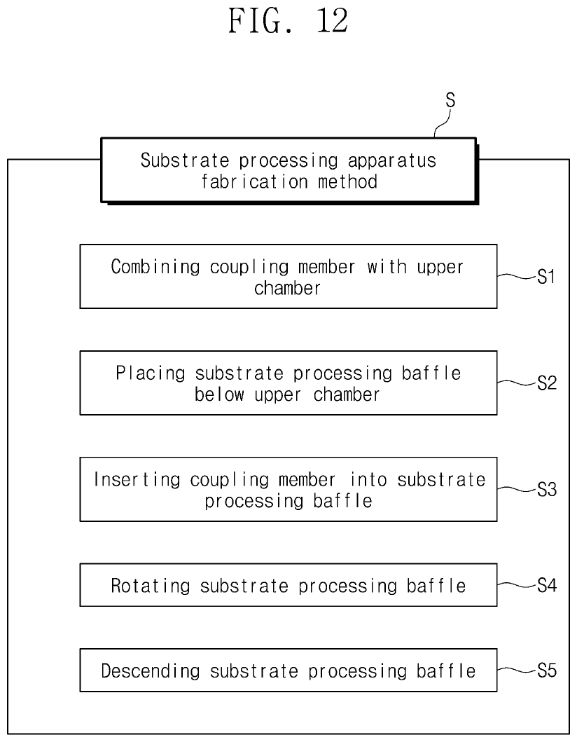

FIG. 12 illustrates a flow chart showing a substrate processing apparatus fabrication method according to some embodiments of the present inventive concept.

Referring to FIG. 12, a substrate processing apparatus fabrication method S may be provided. The substrate processing apparatus fabrication method S may be a way of manufacturing the substrate processing apparatus (see D of FIG. 3) discussed with reference to FIGS. 1 to 11. The substrate processing apparatus fabrication method S may include a step S1 of combining a coupling member with an upper chamber, a step S2 of placing a substrate processing baffle below the upper chamber, a step S3 of inserting the coupling member into the substrate processing baffle, a step S4 of rotating the substrate processing baffle, and a step S5 of descending the substrate processing baffle.

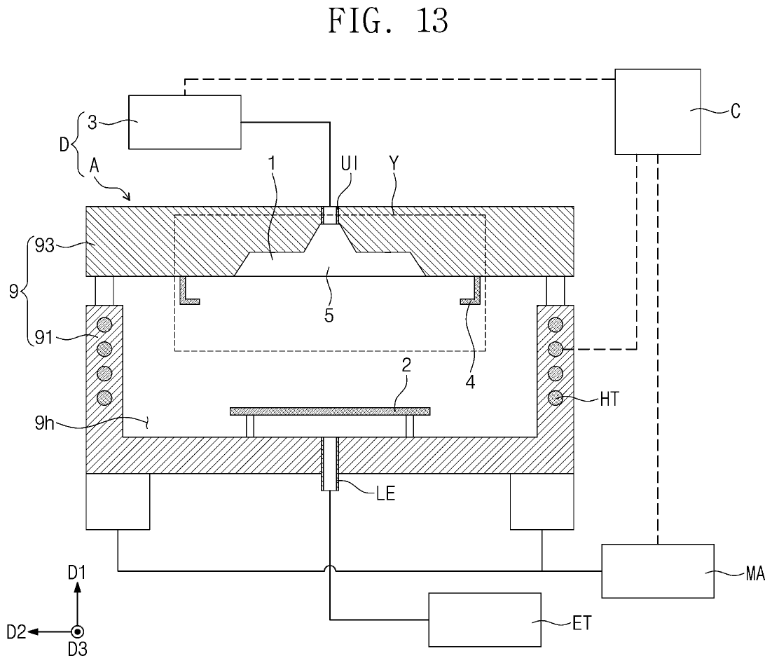

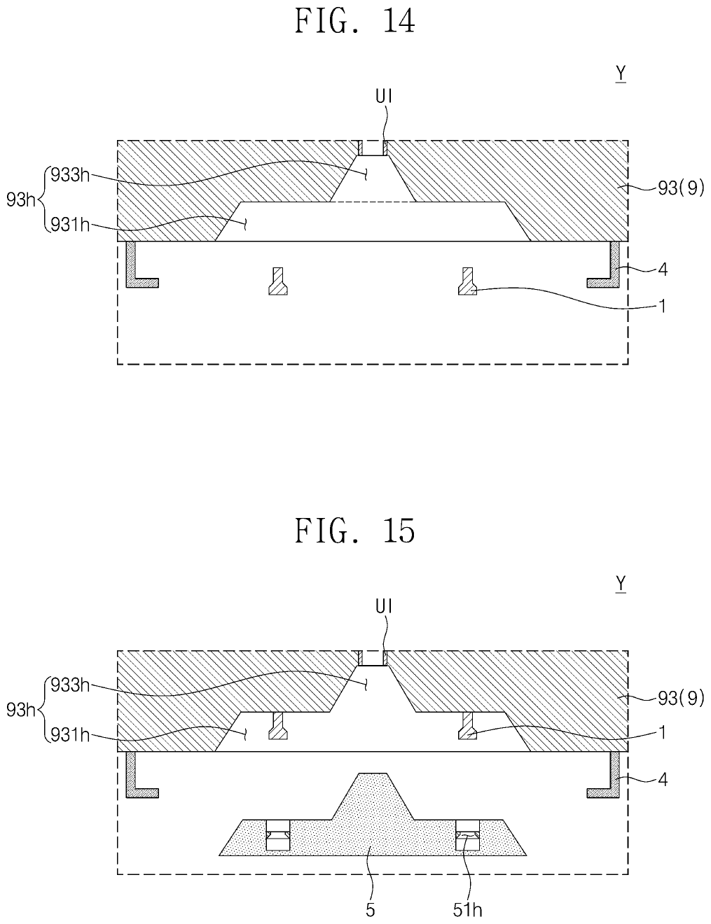

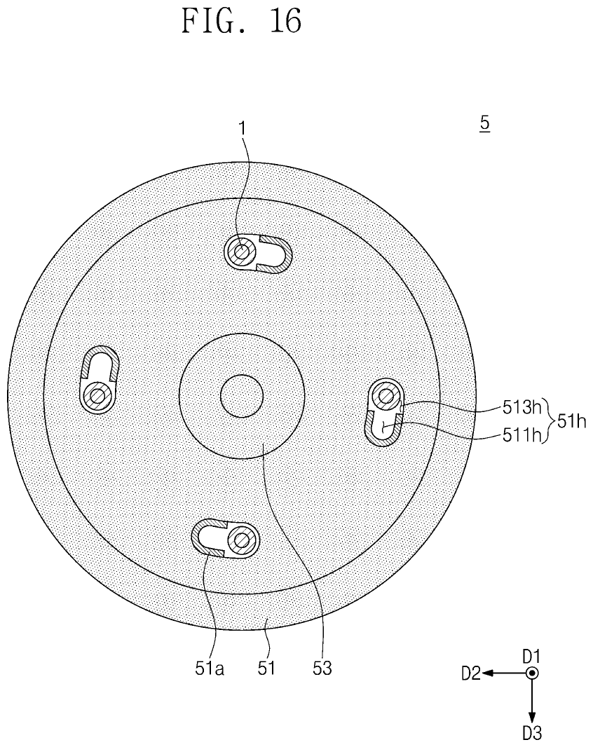

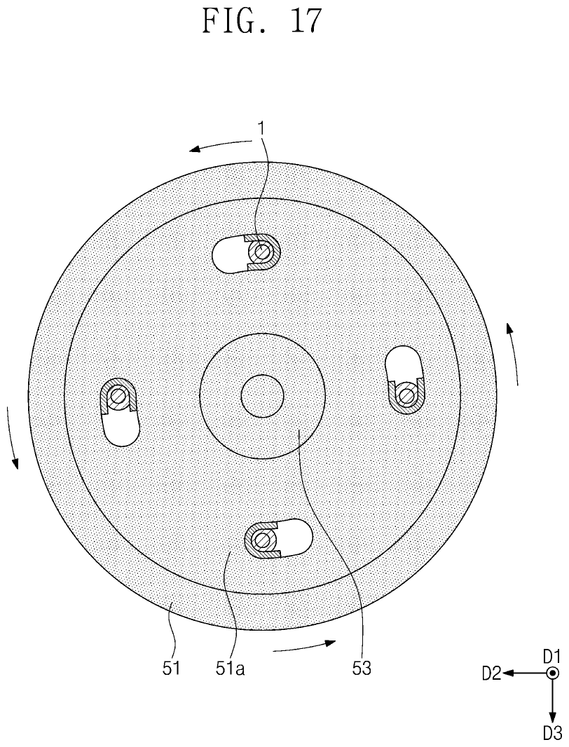

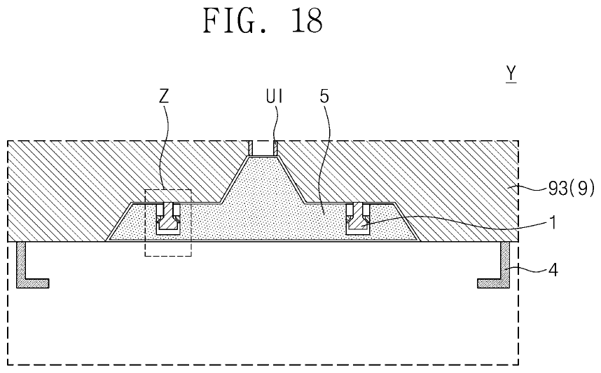

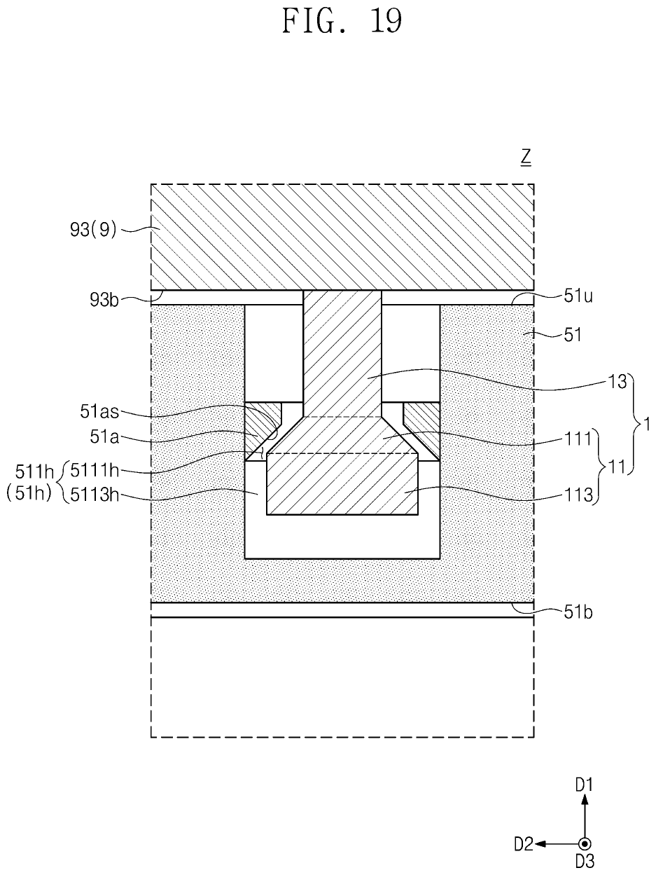

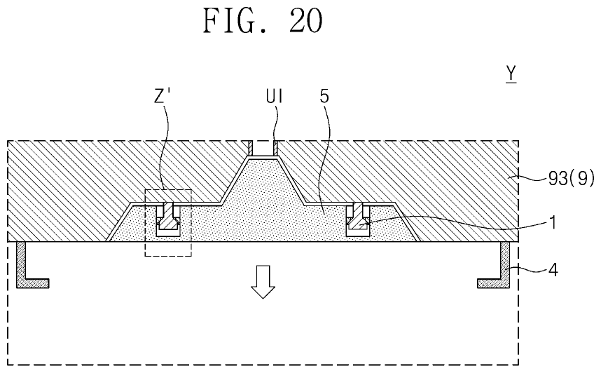

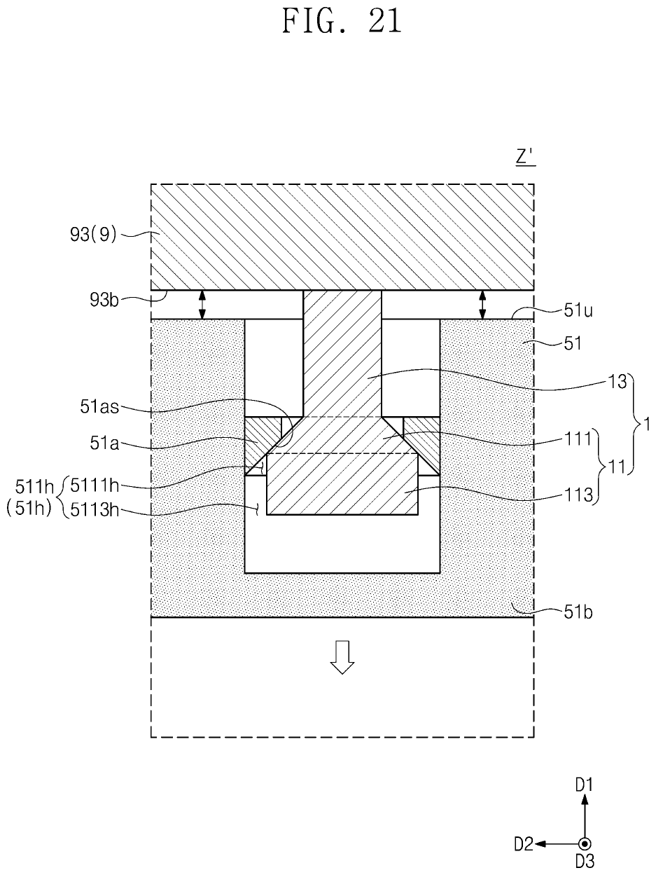

The substrate processing apparatus fabrication method S will be further discussed in detail below with reference to FIGS. 13 to 21.

FIGS. 13 to 21 illustrate diagrams showing the substrate processing apparatus fabrication method of FIG. 12.

Referring to FIGS. 12, 13, 14, and 15, the coupling step S1 may include fixing the coupling member 1 to a bottom surface of the upper chamber 93. For example, in the baffle placement space 93h, the coupling member 1 may be welded to the bottom surface of the upper chamber 93.

Referring to FIGS. 12 and 15, the placement step S2 may include placing the substrate processing baffle 5 below the baffle placement space 93h. Afterwards, the substrate processing baffle 5 may ascend to be disposed in the baffle placement space 93h.

Referring to FIGS. 12, 15, and 16, the insertion step S3 may include inserting the coupling member 1 into the coupling hole 51h. When the substrate processing baffle 5 is disposed in the baffle placement space 93h, the coupling member 1 may be inserted into the coupling hole 51h. A minimum width of the insertion hole 513h may be greater than that of the coupling member 1. Therefore, when the substrate processing baffle 5 ascends to be disposed in the baffle placement space 93h, the coupling member 1 may be inserted into the insertion hole 513h.

Referring to FIGS. 12, 16, 17, 18, and 19, the rotation step S4 may include allowing the placement hole 511h to receive the coupling member 1 that is inserted into the insertion hole 513h. In this step, a lateral surface of the coupling head 11 may be spaced apart from the inclined inner surface 51as.

Referring to FIGS. 12, 20, and 21, the descent step S5 may include allowing the lateral surface of the coupling head 11 to contact the inclined inner surface 51as. For example, when the substrate processing baffle 5 moves downwardly in a state where the coupling member 1 is disposed in the placement hole 511h, the inclined inner surface 51as may be in contact with the lateral surface of the coupling head 11. Therefore, the substrate processing baffle 5 may be in contact with the coupling member 1.

According to a substrate processing baffle, a substrate processing apparatus including the same, and a substrate processing apparatus fabrication method in accordance with some embodiments of the present inventive concept, a coupling member may be inserted into a position setting aperture defined by an inclined inner surface, and thus a substrate processing baffle may be automatically aligned with a coupling member when the substrate processing baffle moves downwardly. For example, it may be possible to automatically set a position of the substrate processing baffle. Therefore, assembly tolerance may be reduced between the substrate processing baffle and the coupling member in assembling the substrate processing baffle. Accordingly, the substrate processing baffle may be disposed on an exact position.

According to a substrate processing baffle, a substrate processing apparatus including the same, and a substrate processing apparatus fabrication method in accordance with some embodiments of the present inventive concept, the substrate processing baffle may be promptly and easily coupled to an upper chamber. Thus, even an unskilled worker may place the substrate processing baffle on its exact position.

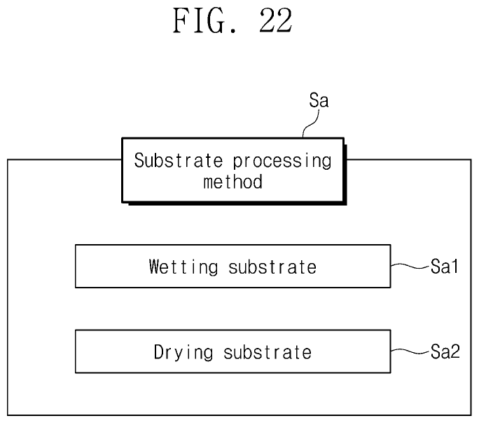

FIG. 22 illustrates a flow chart showing a substrate processing method according to some embodiments of the present inventive concept.

Referring to FIG. 22, a substrate processing method Sa may be provided. The substrate processing method Sa may be a way of treating a substrate by using the substrate processing system (see P of FIG. 1) discussed with reference to FIGS. 1 to 11. The substrate processing method Sa may include a step Sa1 of wetting a substrate and a step Sa2 of drying the substrate.

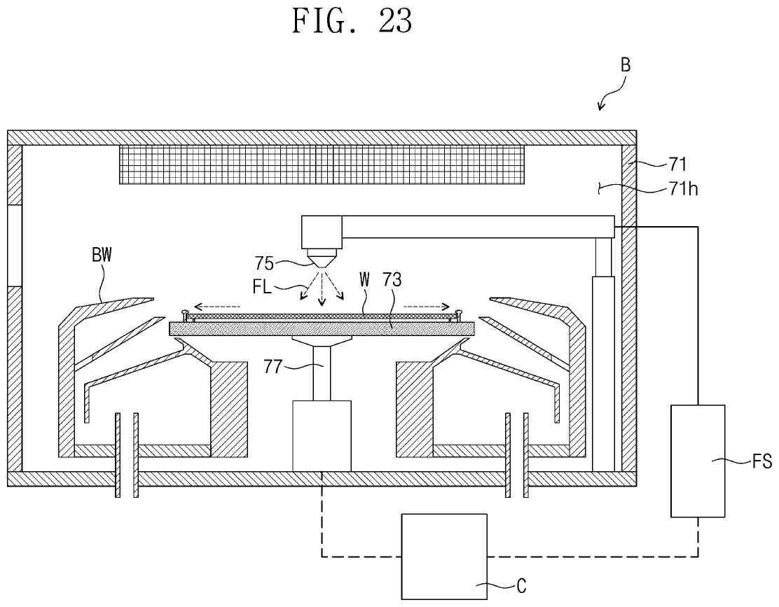

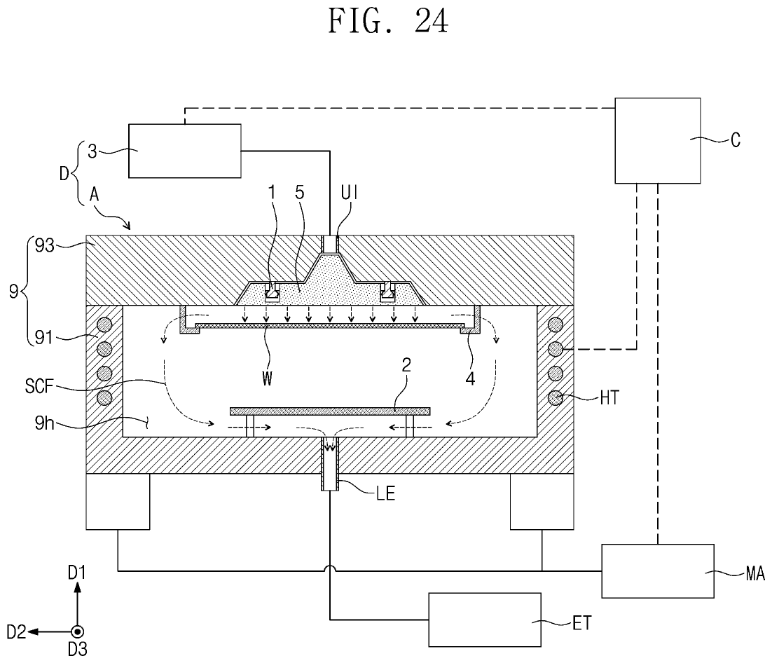

The substrate processing method Sa of FIG. 22 will be further discussed in detail below with reference to FIGS. 23 and 24.

FIGS. 23 and 24 illustrate diagrams showing a substrate processing method according to the flow chart of FIG. 22.

Referring to FIGS. 22 and 23, the wet step Sa1 may include spraying a wetting solution FL onto a substrate W disposed on the wetting stage 73. For example, the wetting solution FL supplied from the wetting solution supply FS may be sprayed through the wetting nozzle 75 onto the substrate W. In this step, the substrate W may rotate. For example, the rotating shaft 77 may turn to rotate the wetting stage 73, thereby rotating the substrate W. The wetting solution FL sprayed onto the substrate W may be uniformly distributed on the substrate W.

Referring to FIGS. 22 and 24, the dry step Sa2 may include supplying the drying space 9h with a supercritical fluid SCF. The supercritical fluid SCF supplied from the supercritical fluid supply 3 may be provided to the dry chamber housing 9. The supercritical fluid SCF supplied from the supercritical fluid supply 3 may move into the fluid inlet UI. The supercritical fluid SCF may be supplied through the substrate processing baffle 5 to the drying space 9h. For example, the supercritical fluid SCF may be introduced into the drying space 9h through the upper flow path (see 53ph of FIG. 10) and the lower flow path (see 51ph of FIG. 10). The supercritical fluid SCF supplied from the drying space 9h may remove liquid on the substrate W. For example, the wetting solution (see FL of FIG. 23) coated on the substrate W in the wet chamber (see B of FIG. 23) may be dried by the supercritical fluid SCF in the dry chamber A. For example, a liquid on the substrate W may be pushed away by the supercritical fluid SCF at a high pressure, and thus the substrate W may be dried.

According to a substrate processing baffle, a substrate processing apparatus including the same, and a substrate processing apparatus fabrication method in accordance with some embodiments of the present inventive concept, a substrate processing baffle may be disposed on an exact position, and a supercritical fluid that passes through the substrate processing baffle may be uniformly supplied to a drying space. Therefore, a substrate dry process may increase in yield.

According to a substrate processing baffle, a substrate processing apparatus including the same, and a substrate processing apparatus fabrication method according to aspects of the present inventive concept, a substrate processing baffle may be exactly coupled to an upper chamber.

According to a substrate processing baffle, a substrate processing apparatus including the same, and a substrate processing apparatus fabrication method according to aspects of the present inventive concept, a fluid may be uniformly sprayed onto a substrate.

According to a substrate processing baffle, a substrate processing apparatus including the same, and a substrate processing apparatus fabrication method according to aspects of the present inventive concept, a substrate processing baffle may be promptly and easily coupled to an upper chamber.

According to a substrate processing baffle, a substrate processing apparatus including the same, and a substrate processing apparatus fabrication method according to aspects of the present inventive concept, a substrate may be fabricated at a high yield.

Effects of the aspects of the present inventive concept are not limited to the mentioned above, other effects which have not been mentioned above will be clearly understood to those skilled in the art from the following description.

Although aspects of the present inventive concept have been described in connection with some embodiments of the present inventive concept illustrated in the accompanying drawings, it will be understood to those skilled in the art that various changes and modifications may be made without departing from the technical spirit and essential feature of the aspects of the present inventive concept. It therefore will be understood that the embodiments described above are just illustrative but not limitative in all aspects.

What is claimed is:

1. A substrate processing baffle, comprising:
a plate body having a central axis that extends in a first direction; and
an upper body on the plate body,
wherein the upper body includes an upper flow path connected to a top surface of the upper body,
wherein the plate body includes:
a lower flow path connected to the upper flow path and a bottom surface of the plate body; and
a coupling hole extending through a top surface of the plate body,
wherein the coupling hole includes a placement hole,
wherein the placement hole includes a position setting aperture whose width decreases with decreasing distance from the top surface of the plate body.

2. The substrate processing baffle of claim 1, wherein the coupling hole further includes an insertion hole on a side of the placement hole and connected to the placement hole,
wherein a minimum width of the insertion hole is greater than a minimum width of the position setting aperture.

3. The substrate processing baffle of claim 2, wherein
the placement hole and the insertion hole are connected to each other in a horizontal direction, and
when viewed in plan, the placement hole and the insertion hole extend in a circumferential direction.

4. The substrate processing baffle of claim 1, wherein each of the plate body and the upper body includes metal.

5. The substrate processing baffle of claim 1, wherein
the coupling hole is one of a plurality of coupling holes, and
the plurality of coupling holes are spaced apart from each other in a circumferential direction.

6. The substrate processing baffle of claim 1, wherein
a height of the coupling hole is less than a height of the plate body, and
the coupling hole does not extend through to the bottom surface of the plate body.

7. The substrate processing baffle of claim 1, wherein
the upper body has a truncated cone shape, and
an axis of the upper body coincides with the central axis of the plate body.

8. A substrate processing apparatus, comprising:
a dry chamber housing that provides a drying space;
a substrate processing baffle in the dry chamber housing; and
a coupling member that connects the dry chamber housing and the substrate processing baffle to each other,
wherein the substrate processing baffle includes a plate body,
wherein the plate body includes:
a lower flow path connected to a bottom surface of the plate body; and
a coupling hole extending through a top surface of the plate body,
wherein the coupling hole includes a placement hole,
wherein at least a portion of the placement hole is defined by an inclined inner surface inclined toward an axis of the placement hole, the axis extending vertically, and
wherein a portion of a lateral surface of the coupling member is in contact with the inclined inner surface.

9. The substrate processing apparatus of claim 8, wherein the coupling member includes a coupling head having a portion whose width increases in a downward direction,
wherein at least a portion of a lateral surface of the coupling head is in contact with the inclined inner surface.

10. The substrate processing apparatus of claim 9, wherein the coupling head has a truncated cone shape.

11. The substrate processing apparatus of claim 8, wherein the coupling hole further includes an insertion hole on a side of the placement hole and connected to the placement hole,
wherein a minimum width of the insertion hole is greater than a minimum width of a position setting aperture defined by the inclined inner surface.

12. The substrate processing apparatus of claim 8, wherein the dry chamber housing includes:
a lower chamber; and
an upper chamber on the lower chamber,
wherein the coupling member is coupled to a bottom surface of the upper chamber.

13. The substrate processing apparatus of claim 12, wherein the upper chamber includes:
a baffle placement space that receives the substrate processing baffle; and
a fluid inlet that upwardly extends from the baffle placement space.

14. The substrate processing apparatus of claim 13, further comprising a supercritical fluid supply that supplies the drying space with a supercritical fluid,
wherein the supercritical fluid supply is connected to the fluid inlet.

15. The substrate processing apparatus of claim 8, further comprising a dry chuck in the dry chamber housing and downwardly spaced apart from the substrate processing baffle.

16. A substrate processing apparatus fabrication method, comprising:
placing a substrate processing baffle below an upper chamber of a dry chamber housing;
inserting a coupling member into the substrate processing baffle; and
descending the substrate processing baffle to fix the coupling member to the substrate processing baffle,
wherein the substrate processing baffle includes a plate body having a central axis that extends in a first direction,
wherein the plate body includes:
a lower flow path connected to a bottom surface of the plate body; and
a coupling hole extending through a top surface of the plate body,
wherein the coupling hole includes a placement hole,
wherein the placement hole includes a position setting aperture whose width decreases with decreasing distance from the top surface of the plate body,
wherein inserting the coupling member into the substrate processing baffle includes inserting the coupling member into the coupling hole, and
wherein descending the substrate processing baffle includes fixing the coupling member into the placement hole.

17. The method of claim 16, wherein the coupling hole further includes an insertion hole on a side of the placement hole,
wherein inserting the coupling member into the coupling hole includes inserting the coupling member into the insertion hole.

18. The method of claim 17, before descending the substrate processing baffle, further comprising rotating the substrate processing baffle,
wherein rotating the substrate process baffle includes allowing the placement hole to receive the coupling member inserted into the insertion hole.

19. The method of claim 16, before placing the substrate processing baffle below the upper chamber, further comprising fixedly combining the coupling member with a bottom surface of the upper chamber.

20. The method of claim 19, wherein fixedly combining the coupling member with the bottom surface includes welding the coupling member to the bottom surface.
